(19) United States
(12) Patent Application Publication
(10) Pub. No.: US 2011/0133858 A1
(43) Pub. Date: Jun. 9, 2011

(54) ELASTIC WAVE ELEMENT AND ELECTRONIC DEVICE USING THE SAME

(76) Inventors: Rei Goto, Osaka (JP); Hidekazu Nakanishi, Osaka (JP); Hiroyuki Nakamura, Osaka (JP)

(21) Appl. No.: 13/056,813

(22) PCT Filed: Aug. 5, 2009
(86) PCT No.: PCT/JP2009/003734

§ 371 Date: Jan. 31, 2011

(30) Foreign Application Priority Data
Aug. 7, 2008 (JP) 2008-203979
Nov. 18, 2008 (JP) 2008-294122

(51) Int. Cl. H03H 9/15; H03H 9/25

(52) U.S. Cl. 333/194

(57) ABSTRACT

An elastic wave device includes a piezoelectric substrate, an IDT electrode disposed on a piezoelectric device, a first dielectric layer disposed on the piezoelectric substrate such that it covers the IDT electrode, and a second dielectric layer disposed over the first dielectric layer. The second dielectric layer propagates transverse waves faster than that on the first dielectric layer. When a film thickness of the second dielectric layer is greater than a wave length of a major wave excited by the IDT electrode, a cut angle of the piezoelectric substrate in indication of Euler angles (φ, θ, Φ) is set to φ≠0°, θ≠0°, and Φ≠0°. This suppresses deterioration of device characteristics.

### TECHNICAL FIELD

The present invention relates to elastic wave devices and electronic equipment using the elastic wave device.

### BACKGROUND ART

A conventional elastic wave device is described with reference to FIGS. 9A and 9B.

FIG. 9A is a schematic sectional view of the conventional elastic wave device. FIG. 9B is a graph indicating a range that an electromechanical coupling coefficient of Rayleigh wave becomes not greater than a predetermined value when a cut angle of piezoelectric substrate is changed in the conventional elastic wave device.

In FIGS. 9A and 9B, conventional elastic wave device 1 includes piezoelectric substrate 2 made of lithium niobate, and IDT electrode 3 disposed on piezoelectric substrate 2. In an area on piezoelectric substrate 2 other than an area where IDT electrode 3 is formed, first dielectric layer 6 made of silicon oxide film is formed in a thickness equivalent to IDT electrode 3. In addition, second dielectric layer 7 made of silicon oxide film covers IDT electrode 3 and first dielectric layer 6.

Normalized film thickness of second dielectric layer 7 is between 0.15λ and 0.40λ, and Φ in cut angles (0°±5°, θ, Φ) of piezoelectric substrate 2 is between 10° and 30°. In addition, if the film thickness of IDT electrode, for example, is 0.06λ, θ and Φ fall in a range of hatched area in FIG. 9B.

This enables to reduce the electromechanical coupling coefficient of Rayleigh wave, which is not a major wave, so as to suppress spurious due to Rayleigh wave. Conventional elastic wave device 1 as configured above sets the cut angle of piezoelectric substrate 2, film thickness of IDT electrode 3, and film thickness of second dielectric layer 7 so as to reduce the electromechanical coupling coefficient of Rayleigh wave. This suppresses a spurious response caused by the Rayleigh wave.

However, if this conventional elastic wave device 1 is a boundary wave device that traps major waves inside the device, the film thickness of IDT electrode 3, film thickness of dielectric layer, and so on often become out of conditions that can suppress Stoneley waves, due to manufacturing variations. This manufacturing variations cause spurious responses by Stoneley waves, resulting in deteriorating device characteristics.

### CITATION LIST

### Patent Literature

[PTL 1] Japanese Patent Unexamined Publication No. 2007-251710

### SUMMARY OF THE INVENTION

The present invention offers an elastic wave device that suppresses deterioration of device characteristics even if there are manufacturing variations.

The elastic wave device of the present invention includes a piezoelectric substrate, an IDT electrode disposed on the piezoelectric substrate, a first dielectric layer disposed on the piezoelectric substrate such that it covers the IDT electrode, and a second dielectric layer disposed over the first electric layer. Transverse waves propagate faster on the second dielectric layer than that on the first dielectric layer. When the film thickness of second dielectric layer is more than 0.8 times as large as wavelength λ of major waves excited by IDT electrode, a cut angle of piezoelectric substrate in indication of Euler angles (φ, θ, Φ) is set to φ≠0°, θ≠0°, and Φ≠0°.

By shifting cut angle φ of piezoelectric substrate from 0° in the elastic wave device of the present invention, a power flow angle of SH wave, which is a major wave, becomes not greater than a predetermined value, and a power flow angle of Stoneley wave becomes not less than a predetermined value. In other words, in a boundary wave device in which manufacturing variations often occur, deterioration of device characteristics can be suppressed to a permissible level even if the film thickness of IDT electrode, film thickness of dielectric layer, and so on become out of conditions for suppressing Stoneley waves and the power flow angle of Stoneley waves become slightly smaller.

### BRIEF DESCRIPTION OF DRAWINGS

FIG. 1 is a schematic sectional view of an elastic wave device in accordance with a first exemplary embodiment of the present invention.

FIG. 2 illustrates characteristics of the elastic wave device in accordance with the first exemplary embodiment of the present invention.

FIG. 3 illustrates characteristics of the elastic wave device in accordance with the first exemplary embodiment of the present invention.

FIG. 4 illustrates characteristics of the elastic wave device in accordance with the first exemplary embodiment of the present invention.

FIG. 5 illustrates characteristics of the elastic wave device in accordance with the first exemplary embodiment of the present invention.

FIG. 6 illustrates characteristics of the elastic wave device in accordance with the first exemplary embodiment of the present invention.

FIG. 7 illustrates characteristics of the elastic wave device in accordance with the first exemplary embodiment of the present invention.

FIG. 8 illustrates characteristics of the elastic wave device in accordance with the first exemplary embodiment of the present invention.

FIG. 9A is a schematic sectional view of a conventional elastic wave device.

FIG. 9B illustrates a range of electromechanical coupling coefficient of Rayleigh wave in the conventional elastic wave device.

### DETAILED DESCRIPTION OF PREFERRED EMBODIMENTS

### First Exemplary Embodiment

An elastic wave device in the first exemplary embodiment is described below with reference to drawings.

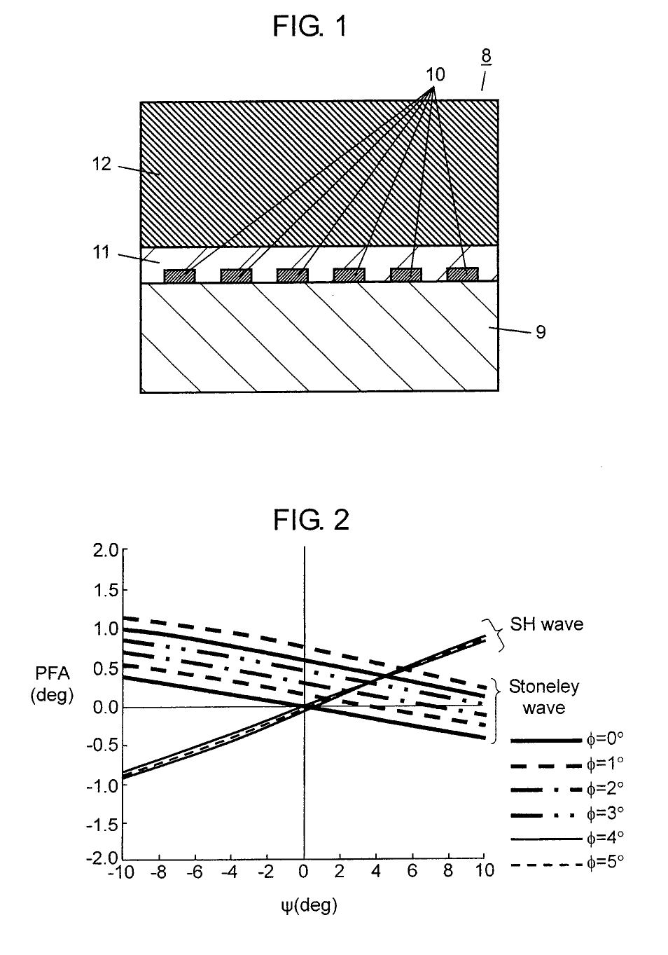

FIG. 1 is a schematic sectional view of elastic wave device 8 in the first exemplary embodiment of the present invention. In FIG. 1, elastic wave device 8 includes piezoelectric substrate 9, IDT (Inter-Digital Transducer) electrode 10 disposed on piezoelectric substrate 9, first dielectric layer 11 disposed on piezoelectric substrate 9 such that first dielectric layer 11 covers IDT electrode 10, and second dielectric layer 12 provided over first dielectric layer 11.

Piezoelectric substrate 9 is formed of, for example, lithium niobate, lithium tantalite, or potassium niobate. A cut angle of this piezoelectric substrate 9 in indication of Euler angles is φ≠0°, θ≠0°, and Φ≠0°. For example, the cut angle of piezoelectric substrate 9 is 1.3°<φ<5.5°, −70°<θ<−60°, and −3.4°<Φ<0°.

IDT electrode 10 is, for example, single metal of aluminum, copper, silver, gold, titanium, tungsten, Molybdenum, platinum, or chromium, or an alloy mainly consists of these metals.

First dielectric layer 11 is, for example, made of silicon oxide. However, first dielectric layer 11 may be any medium that has frequency-temperature characteristic opposite to that of piezoelectric substrate 9. This improves the frequency-temperature characteristic.

Second dielectric layer 12 is formed of a medium that propagates transverse waves faster than the speed of transverse waves propagating on first dielectric layer 11. For example, diamond, silicone, silicone nitride, aluminum nitride, or aluminum oxide is used. The film thickness of this second dielectric layer 12 is not less than 0.8 times as large as wavelength λ of SH wave, which is a major wave. This enables to trap the major wave inside elastic wave device 8. To almost completely trap the major wave inside elastic wave device 8, the film thickness of second dielectric layer 12 is preferably not less than wavelength λ of SH wave that is the major wave.

In the above structure, a power flow angle of SH wave that is the major wave becomes not greater than a predetermined value, and a power flow angle of Stoneley wave becomes not less than the predetermined value by shifting cut angle φ of piezoelectric substrate 9 from 0°. The power flow angle is an angle formed by a direction of propagating phase velocity and a direction of group velocity when waves are excited by IDT electrode 10.

Accordingly, in a boundary wave device in which manufacturing variations frequently occur, deterioration of device characteristics can be suppressed to a permissible level even if the film thickness of IDT electrode 10, the film thickness of dielectric layer, and so on are out of conditions that can suppress Stoneley waves, and the power flow angle of Stoneley waves becomes slightly smaller than the predetermined value. This is detailed below.

FIG. 2 illustrates characteristics of the elastic wave device in the first exemplary embodiment of the present invention. In FIG. 2, a vertical axis indicates PFA (power flow angle) of SH wave that is major wave (Unit: deg) or PFA (power flow angle) of Stoneley wave that is undesired wave (Unit: deg). FIG. 2 shows cases when the cut angle of piezoelectric substrate 9 is θ=−65° and φ=0°, 1°, 2°, 3°, 4°, and 5°.

In elastic wave device 8, lithium niobate is used as piezoelectric substrate 9, and copper with normalized film thickness of 0.09λ (λ is wavelength of SH wave) as IDT electrode 10. Silicon oxide with normalized film thickness of 0.2λ is used as first dielectric layer 11, and silicon nitride with normalized film thickness λ is used as second dielectric layer 12.

Focusing on SH wave that is major wave in FIG. 2, it can be found that Φ that sets 0° to PFA of SH wave that is major wave changes from 0° by changing φ. Accordingly, by using Φ that sets 0° to PFA of SH wave that is major wave, deterioration of Q value of SH wave that is major wave can be suppressed. Deterioration of Q value can thus be suppressed when an absolute value of power flow angle of SH wave excited by IDT electrode 10 becomes less than 0.3°.

Focusing on Stoneley wave that is undesired wave, it can be found that PFA of Stoneley wave that is undesired wave also becomes 0° if Φ that sets 0° to PFA of SH wave that is major wave is adopted in the case that cut angle φ of piezoelectric substrate 9 is 0°. Therefore, elastic wave device 8 in the first exemplary embodiment can shift PFA of Stoneley wave that is undesired wave from 0° by setting a value other than 0° to cut angle φ of piezoelectric substrate 9 if Φ that sets 0° to PFA of SH wave that is major wave is adopted.

Based on the above results, a Q value of Stoneley wave that is undesired response can be reduced by changing cut angle φ of piezoelectric substrate 9 from 0°. This enables selective suppression of spurious response.

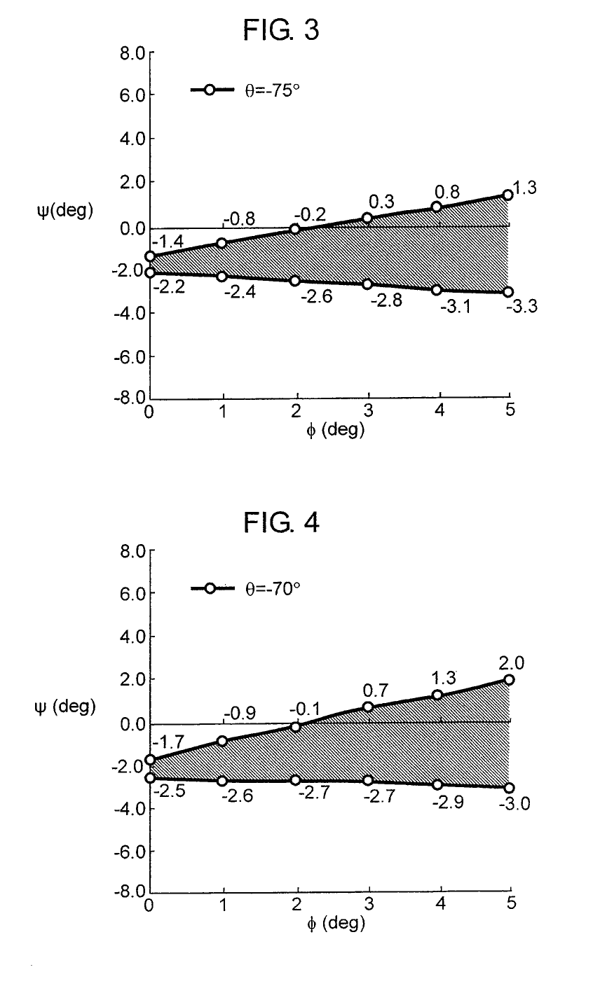

Next is described a range of cut angles of piezoelectric substrate 9 when an absolute value of power flow angle of SH wave excited by IDT electrode 10 becomes less than 0.3° and an absolute value of power flow angle of Stoneley wave excited by IDT electrode 10 becomes not less than 0.3° in the above elastic wave device 8, with reference to FIGS. 3 to 6.

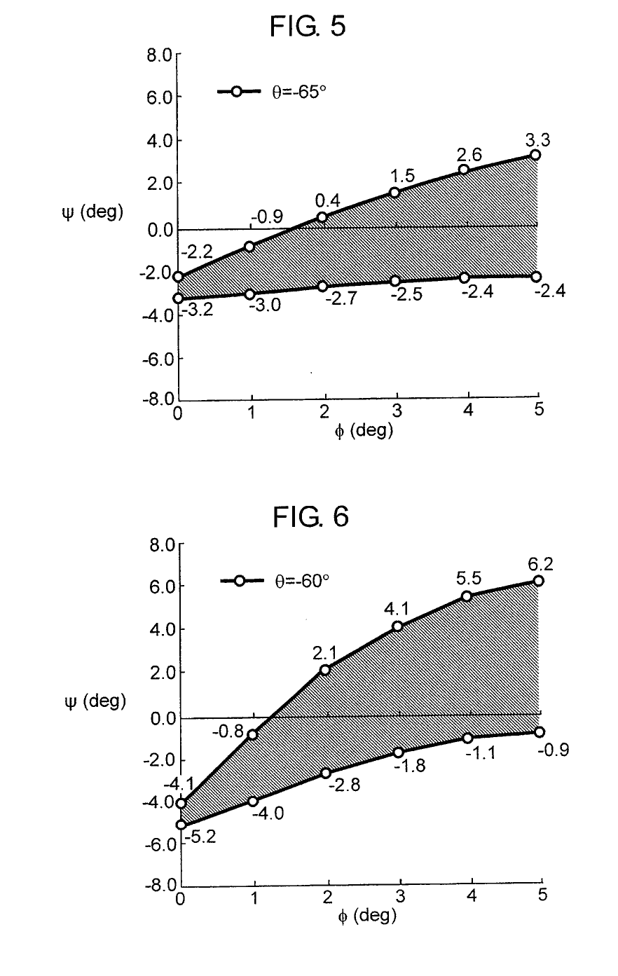

FIGS. 3 to 6 are charts illustrating characteristics of elastic wave device in the first exemplary embodiment of the present invention. FIGS. 3 to 6 show ranges of cut angles of piezoelectric substrate 9 when the absolute value of power flow angle of SH wave is less than 0.3° and the absolute value of power flow angle of Stoneley wave is not less than 0.3°. In these charts, ranges of φ and Φ are hatched when θ is −75° in FIG. 3, θ is −70° in FIG. 4, θ is −65° in FIG. 5, and θ is −60° in FIG. 6, provided that the cut angle of piezoelectric substrate is indicated by Euler angles (φ, θ, Φ).

Here, lithium niobate is used as piezoelectric substrate 9, copper with normalized film thickness of 0.09λ (λ is wavelength of SH wave) is used as IDT electrode 10, silicon oxide with normalized film thickness of 0.2λ is used as first dielectric layer 11, and silicon nitride with normalized film thickness λ is used as second dielectric layer 12.

As shown in FIGS. 3 to 6, the absolute value of power flow angle of SH wave excited by IDT electrode 10 becomes less than 0.3° and the absolute value of power flow angle of Stoneley wave excited by IDT electrode 10 becomes not less than 0.3° when the cut angle of piezoelectric substrate 9 satisfies the following conditions.

In other words, the cut angle of piezoelectric substrate 9 of elastic wave device 8 satisfies the following conditions.

i) When −77.5°≦θ<−72.5°,

−0.5°≦φ<0.5° and −2.2°≦Φ<−1.4°

or

0.5°≦φ<1.5° and −2.4°≦Φ<−0.8°

or

1.5°≦φ<2.5° and −2.6°≦Φ<−0.2°

or

2.5°≦φ<3.5° and −2.8°≦Φ<0.3°

or

3.5°≦φ<4.5° and −3.1°≦Φ<0.8°

or

4.5°≦φ<5.5° and −3.3°≦Φ<1.3°

ii) When −72.5°≦θ<−67.5°,

−0.5°≦φ<0.5° and −2.5°≦Φ<−1.7°

or

0.5°≦φ<1.5° and −2.6°≦Φ<−0.9°

or

1.5°≦φ<2.5° and −2.7°≦Φ<−0.1°

or

2.5°≦φ<3.5° and −2.7°≦Φ<0.7°

or

3.5°>φ<4.5° and −2.9°≦Φ<1.3°

or

4.5°≦φ<5.5° and −3°≦Φ<2°

iii) When −67.5°≦θ<−62.5°,

−0.5°≦φ<0.5° and −3.2°≦Φ<−2.2°

or

0.5°≦φ<1.5° and −3°≦Φ<−0.9°

or

1.5°≦φ<2.5° and −2.7°≦Φ<0.4°

or

2.5°≦φ<3.5° and −2.5°≦Φ<1.5°

or

3.5°≦φ<4.5° and −2.4°≦Φ<2.6°

or

4.5°≦φ<5.5° and −2.4°≦Φ<3.3°

iv) When −62.5°≦θ<−57.5°,

−0.5°≦φ<0.5° and −5.2°≦Φ<−4.1°

or

0.5°≦φ<1.5° and −4°≦Φ<−0.8°

or

1.5°≦φ<2.5° and −2.8°≦Φ<2.1°

or

2.5°≦φ<3.5° and −1.8°≦Φ<4.1°

or

3.5°≦φ<4.5° and −1.1≦Φ<5.5°

or

4.5°≦φ<5.5° and −0.9°≦Φ<6.2°

When the above conditions are satisfied, the power flow angle of SH wave that is major wave becomes less than 0.3°, and the absolute value of power flow angle of Stoneley wave becomes not less than 0.3°. Accordingly, propagation losses of SH wave can be reduced, and also spurious response of Stoneley wave can be suppressed.

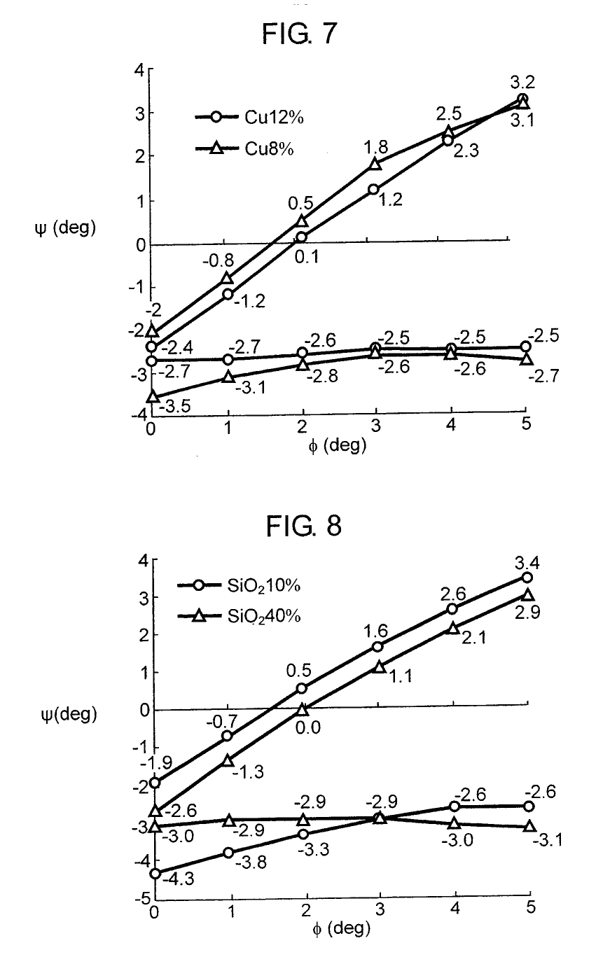

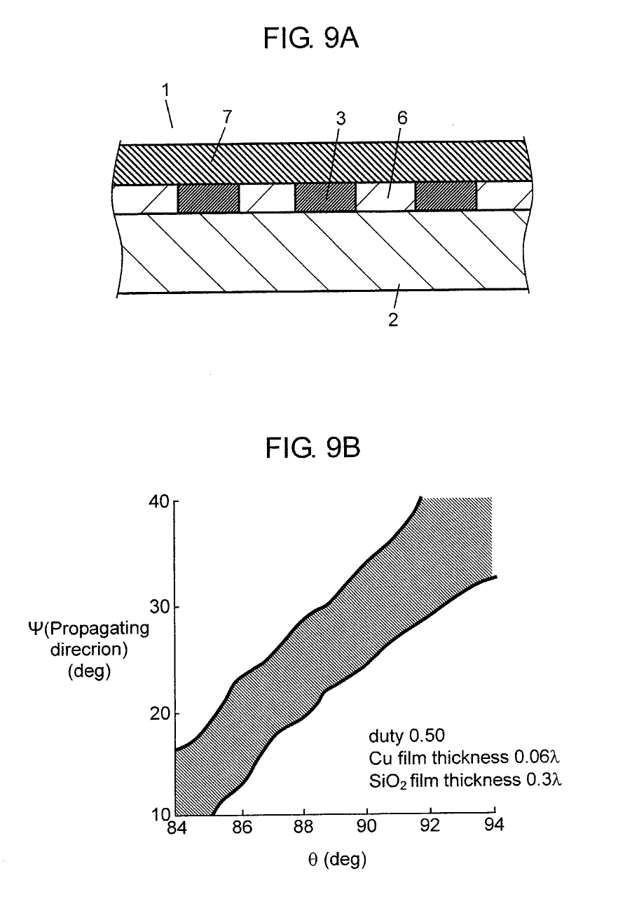

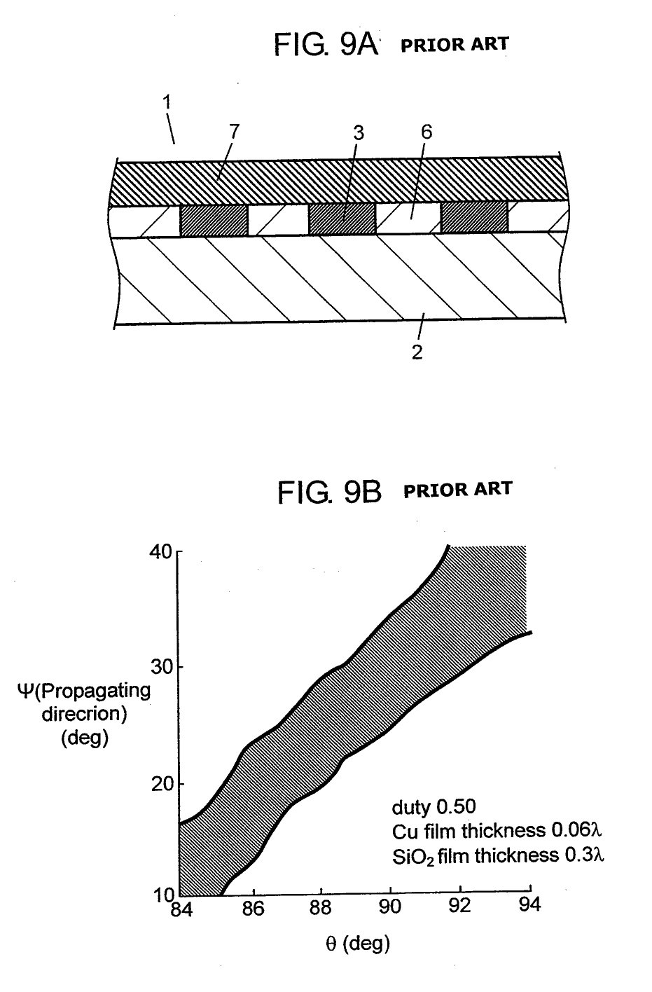

FIG. 7 shows characteristics of the elastic wave device in the first exemplary embodiment of the present invention. More specifically, it shows a range of cut angles of piezoelectric substrate 9 that makes the absolute value of power flow angle of SH wave less than 0.3° and the absolute value of power flow angle of Stoneley wave not less than 0.3° when the normalized film thickness of IDT electrode 10 is 0.08λ (λ is wavelength of SH waves) or 0.12λ.

In FIG. 7, an area between two dotted lines connecting triangles shows the case when the film thickness of IDT electrode 10 is 0.08λ. An area between two dotted lines connecting circles shows the case when the film thickness of IDT electrode 10 is 0.12λ. Elastic wave device 8 shown in FIG. 7 has the structure same as elastic wave device 8 shown in FIG. 5 except for the film thickness of IDT electrode 10.

FIG. 8 shows characteristics of the elastic wave device in the first exemplary embodiment of the present invention. More specifically, it shows a range of cut angles of piezoelectric substrate 9 that makes the absolute value of power flow angle of SH wave less than 0.3° and the absolute value of power flow angle of Stoneley wave not less than 0.3° when the normalized film thickness of first dielectric layer 11 is 0.1λ (λ is wavelength of SH wave) or 0.4λ.

In FIG. 8, an area between two dotted lines connecting triangles shows the case when the film thickness of first dielectric layer 11 is 0.4λ. An area between two dotted lines connecting circles shows the case when the film thickness of first dielectric layer 11 is 0.1λ. Elastic wave device 8 shown in FIG. 8 has the structure same as elastic wave device 8 shown in FIG. 5 except for the film thickness of first dielectric layer 11.

It is apparent from FIGS. 7 and 8 that the ranges of cut angles of piezoelectric substrate 9 that make the absolute value of power flow angle of SH wave less than 0.3° and the absolute value of power flow angle of Stoneley wave not less than 0.3° also depend on the film thickness and density of IDT electrode 10 and the film thickness of first dielectric layer 11.

Correction functions F1 and F1 for cut angle Φ of piezoelectric substrate 9 that satisfies the above conditions when the film thickness and density of IDT electrode 10 and the film thickness of first dielectric layer 11 change are expressed by Equation 1 and Equation 2, respectively.

F1 is the correction function for the upper limit of Φ that satisfies the above conditions relative to φ. F2 is the correction function for lower limit of Φ that satisfies the above conditions relative to φ. The elastic wave device before correction is the same as above elastic wave device 8. In other words, elastic wave device 8 includes first dielectric layer 11 made of silicon oxide with the normalized film thickness of 0.2λ and IDT electrode 10 made of copper with the normalized film thickness of 0.09λ.

$$\begin{matrix}F 1 = \frac{\frac{ah}{λ} - 0.09}{0.12 - 0.08} g 1 ( φ ) + \frac{\frac{H}{λ} - 0.2}{0.4 - 0.2} h 1 ( φ ) & [ Equation 1 ] \\ F 2 = \frac{\frac{ah}{λ} - 0.09}{0.12 - 0.08} g 2 ( φ ) + \frac{\frac{H}{λ} - 0.2}{0.4 - 0.2} h 2 ( φ ) & [ Equation 2 ]\end{matrix}$$

Whereas, h is the film thickness of IDT electrode 10, a is the ratio of density of IDT electrode 10 to density of copper, and H is the film thickness of first dielectric layer 11.

The above g1 (φ), g2 (φ), h1 (φ), and h2 (φ) are expressed by Equation 3, Equation 4, Equation 5, and Equation 6 below.

g1(φ)=0.0352φ²−0.0852φ−0.3795 [Equation 3]

g2(φ)=0.0589φ²−0.4089φ+0.7821 [Equation 4]

h1(φ)=0.0161φ²−0.1175φ+0.6964 [Equation 5]

h2(φ)=0.0339φ²+0.5496φ−1.3464 [Equation 6]

Here, the above g1 (φ) and g2 (φ) are correction functions that show dependency on the film thickness and density of IDT electrode 10. The above h1 (φ) and h2 (φ) are correction functions that show dependency on the film thickness of first dielectric layer 11.

In other words, when correction functions F1 and F2 are expressed using Equation 1 and Equation 2, the cut angle of piezoelectric substrate 9 in elastic wave device 8 satisfies the following conditions.

i) When −0.77.5°≦θ<−72.5°,

−0.5°≦φ<0.5° and −2.2°+F2≦Φ<−1.4°+F1

or

0.5°≦φ<1.5° and −2.4°+F2≦Φ<−0.8°+F1

or

1.5°≦φ<2.5° and −2.6°+F2≦Φ<−0.2°+F1

or

2.5°≦φ<3.5° and −2.8°+F2≦Φ<0.3°+F1

or

3.5°≦φ<4.5° and −3.1°+F2≦Φ<0.8°+F1

or

4.5°≦φ<5.5° and −3.3°+F2≦Φ<1.3°+F1

ii) When −72.5°≦θ<−67.5°,

−0.5°≦φ<0.5° and −2.5°+F2≦Φ<−1.7°+F1

or

0.5°≦φ<1.5° and −2.6°+F2≦Φ<−0.9°+F1

or

1.5°≦φ<2.5° and −2.7°+F2≦Φ<−0.1°+F1

or

2.5°≦φ<3.5° and −2.7°+F2≦Φ<0.7°+F1

or

3.5°>φ<4.5° and −2.9°+F2≦Φ<1.3°+F1

or

4.5°≦φ<5.5° and −3°+F2≦Φ<2°+F1

iii) When −67.5°≦θ<−62.5°,

−0.5°≦φ<0.5° and −3.2°+F2≦Φ<−2.2°+F1

or

0.5°≦φ<1.5° and −3°+F2≦Φ<−0.9°+F1

or

1.5°≦φ<2.5° and −2.7°+F2≦Φ<0.4°+F1

or

2.5°≦φ<3.5° and −2.5°+F2≦Φ<1.5°+F1

or

3.5°≦φ<4.5° and −2.4°+F2≦Φ<2.6°+F1

or

4.5°≦φ<5.5° and −2.4°+F2≦Φ<3.3°+F1

iv) When −62.5°≦θ<−57.5°,

−0.5°≦φ<0.5° and −5.2°+F2≦Φ<−4.1°+F1

or

0.5°≦φ<1.5° and −4°+F2≦Φ<−0.8°+F1

or

1.5°≦φ<2.5° and −2.8°+F2≦Φ<2.1°+F1

or

2.5°≦φ<3.5° and −1.8°+F2≦Φ<4.1°+F1

or

3.5°≦φ<4.5° and −1.1°+F2≦Φ<5.5°+F1

or

4.5°≦φ<5.5° and −0.9°+F2≦Φ<6.2°+F1

When the above conditions are satisfied, the absolute value of power flow angle of SH wave that is major wave becomes less than 0.3°, and the absolute value of power flow angle of Stoneley wave becomes not less than 0.3°. Accordingly, propagation losses of SH waves can be reduced, and also spurious response of Stoneley waves can be suppressed.

Elastic wave device 8 in the first exemplary embodiment may be applied to a resonator (not illustrated), or a filter (not illustrated) such as a ladder filter and DMS filter. In addition, elastic wave device 8 may be applied to electronic equipment including this filter, a semiconductor integrated circuit device (not illustrated) connected to the filter, and a reproducing unit connected to the semiconductor integrated circuit device (not illustrated). This improves the communications quality of a resonator, filter, and electronic equipment.

### INDUSTRIAL APPLICABILITY

The elastic wave device of the present invention suppresses deterioration of device characteristics, and is applicable to electronic equipment such as mobile phones.

### REFERENCE MARKS IN THE DRAWINGS

8 Elastic wave device
9 Piezoelectric substrate
10 IDT electrode
11 First dielectric layer
12 Second dielectric layer

1. An elastic wave device comprising:
a piezoelectric substrate;
an IDT electrode disposed on the piezoelectric substrate;
a first dielectric layer disposed on the piezoelectric substrate, the first dielectric layer covering the IDT electrode; and
a second dielectric layer disposed over the first dielectric layer, the second dielectric layer propagating a transverse wave faster than a speed of a transverse wave propagating on the first dielectric layer;
wherein
a film thickness of the second dielectric layer is more than 0.8 times as large as wavelength λ of SH wave excited by the IDT electrode; and
a cut angle of the piezoelectric substrate in indication of Euler angles (φ, θ, and Φ) is φ≠0°, θ≠0°, and Φ≠0°.

2. The elastic wave device of claim 1,
wherein
the cut angle of the piezoelectric substrate is a value that makes an absolute value of a power flow angle of the SH wave excited by the IDT electrode to be less than 0.3°, and makes an absolute value of a power flow angle of the Stoneley wave excited by the IDT electrode to be not less than 0.3°.

3. The elastic wave device of claim 1,
wherein
the piezoelectric substrate is formed of lithium niobate, and
the cut angle of the piezoelectric substrate in indication of Euler angles (φ, θ, and Φ) satisfies:
−0.5°≦φ<5.5°,
−77.5°≦θ<−57.5°, and
−5.2°≦Φ<6.2°.

4. The elastic wave device of claim 1,
wherein
the piezoelectric substrate is formed of lithium niobate, and
the cut angle of the piezoelectric substrate in indication of Euler angles (φ, θ, and Φ) satisfies:
i) When −77.5°≦θ<−72.5°,
−0.5°≦φ<0.5° and −2.2°≦Φ<−1.4°
or
0.5°≦φ<1.5° and −2.4°≦Φ<−0.8°
or
1.5°≦φ<2.5° and −2.6°≦Φ<−0.2°
or
2.5°≦φ<3.5° and −2.8°≦Φ<0.3°
or
3.5°≦φ<4.5° and −3.1°≦Φ<0.8°
or
4.5°≦φ<5.5° and −3.3°≦Φ<1.3°
ii) When −72.5°≦θ<−67.5°,
−0.5°≦φ<0.5° and −2.5°≦Φ<−1.7°
or
0.5°≦φ<1.5° and −2.6°≦Φ<−0.9°
or
1.5°≦φ<2.5° and −2.7°≦Φ<−0.1°
or
2.5°≦φ<3.5° and −2.7°≦Φ<0.7°
or
3.5°≦φ<4.5° and −2.9°≦Φ<1.3°
or
4.5°≦φ<5.5° and −3°≦Φ<2°
iii) When −67.5°≦θ<−62.5°,
−0.5°≦θ<0.5° and −3.2°≦Φ<−2.2°
or
0.5°≦φ<1.5° and −3°≦Φ<−0.9°
or
1.5°≦φ<2.5° and −2.7°≦Φ<0.4°
or
2.5°≦φ<3.5° and −2.5°≦Φ<1.5°
or
3.5°≦φ<4.5° and −2.4°≦Φ<2.6°
or
4.5°≦φ<5.5° and −2.4°≦Φ<3.3°
iv) When −62.5°≦θ<−57.5°,
−0.5°≦φ<0.5° and −5.2°≦Φ<−4.1°
or
0.5°≦φ<1.5° and −4°≦Φ<−0.8°
or
1.5°≦φ<2.5° and −2.8°≦Φ<2.1°
or
2.5°≦φ<3.5° and −1.8°≦Φ<4.1°
or
3.5°≦φ<4.5° and −1.1≦Φ<5.5°
or
4.5°≦φ<5.5° and −0.9°≦Φ<6.2°.

5. The elastic wave device of claim 1, wherein
the piezoelectric substrate is formed of lithium niobate; and
when the cut angle of the piezoelectric substrate is indicated by Euler angles (φ, θ, and Φ), and
correction functions F1 and F2 are:
$$\begin{matrix}F 1 = \frac{\frac{ah}{λ} - 0.09}{0.12 - 0.08} g 1 ( φ ) + \frac{\frac{H}{λ} - 0.2}{0.4 - 0.2} h 1 ( φ ) & [ Equation 1 ] \\ F 2 = \frac{\frac{ah}{λ} - 0.09}{0.12 - 0.08} g 2 ( φ ) + \frac{\frac{H}{λ} - 0.2}{0.4 - 0.2} h 2 ( φ ) & [ Equation 2 ]\end{matrix}$$
whereas h is a film thickness of the IDT electrode, a is a ratio of a density of the IDT electrode to a density of copper, and H is a film thickness of the first dielectric layer; and
the g1 (φ), the g2 (φ), the h1 (φ), and the h2 (φ) are:
g1(φ)=0.0352φ²−0.0852φ−0.3795 [Equation 3]
g2(φ)=0.0589φ²−0.4089φ+0.7821 [Equation 4]
h1(φ)=0.0161φ²−0.1175φ+0.6964 [Equation 5]
h2(φ)=0.0339φ²+0.5496φ−1.3464; [Equation 2]
the cut angle of the piezoelectric substrate satisfies:
i) When −77.5°≦θ<−72.5°,
−0.5°≦φ<0.5° and −2.2°+F2≦φ<−1.4°+F1
or
0.5°≦φ<1.5° and −2.4°+F2≦φ<−0.8°+F1
or
1.5°≦φ<2.5° and −2.6°+F2≦φ<−0.2°+F1
or
2.5°≦φ<3.5° and −2.8°+F2≦φ<0.3°+F1
or
3.5°≦φ<4.5° and −3.1°+F2≦φ<0.8°+F1
or
4.5°≦φ<5.5° and −3.3°+F2≦φ<1.3°+F1
ii) When −72.5°≦θ<−67.5°,
−0.5°≦φ<0.5° and −2.5°+F2≦φ<−1.7°+F1
or
0.5°≦φ<1.5° and −2.6°+F2≦φ<−0.9°+F1
or
1.5°≦φ<2.5° and −2.7°+F2≦φ<−0.1°+F1
or
2.5°≦φ<3.5° and −2.7°+F2≦φ<0.7°+F1
or
3.5°≦φ<4.5° and −2.9°+F2≦φ<1.3°+F1
or
4.5°≦φ<5.5° and −3°+F2≦φ<2°+F1
iii) When −67.5°≦θ<−62.5°,
−0.5°≦φ<0.5° and −3.2°+F2≦φ<−2.2°+F1
or
0.5°≦φ<1.5° and −3°+F2≦φ<−0.9°+F1
or
1.5°≦φ<2.5° and −2.7°+F2≦φ<0.4°+F1
or
2.5°≦φ<3.5° and −2.5°+F2≦φ<1.5°+F1
or
3.5°≦φ<4.5° and −2.4°+F2≦φ<2.6°+F1
or
4.5°≦φ<5.5° and −2.4°+F2≦φ<3.3°+F1
iv) When −62.5°≦θ<−57.5°,
−0.5°≦φ<0.5° and −5.2°+F2≦φ<−4.1°+F1
or
0.5°≦φ<1.5° and −4°+F2≦φ<−0.8°+F1
or
1.5°≦φ<2.5° and −2.8°+F2≦φ<2.1°+F1
or
2.5°≦φ<3.5° and −1.8°+F2≦φ<4.1°+F1
or
3.5°≦φ<4.5° and −1.1°+F2≦φ<5.5°+F1
or
4.5°≦φ<5.5° and −0.9°+F2≦φ<6.2°+F1.

6. Electronic equipment comprising:
the elastic wave device of claim 1; and
a semiconductor integrated circuit device connected to the elastic wave device.
